(19) United States
(12) Patent Application Publication
(10) Pub. No.: US 2024/0298412 A1
(43) Pub. Date: Sep. 5, 2024

(54) Circuit board

(71) Applicant: AAC Microtech (Changzhou) Co., Ltd., Changzhou (CN)

(72) Inventor: Guohui Chen, Changzhou (CN)

(21) Appl. No.: 18/325,086

(22) Filed: May 29, 2023

Related U.S. Application Data
(63) Continuation of application No. PCT/CN2023/089506, filed on Apr. 20, 2023.

(30) Foreign Application Priority Data
Mar. 3, 2023 (CN) 202320388761.3

(51) Int. Cl. H05K 3/24; H05K 1/02

(52) U.S. Cl. CPC H05K 3/243; H05K 1/0298; H05K 2203/068; H05K 2203/0723

(57) ABSTRACT

The present disclosure discloses a circuit board including a substrate layer and a conductive layer attached to one side of the substrate layer, the conductive layer being divided into a copper-plated area and a non-copper-plated area adjacent to the copper-plated area, the conductive layer having a greater thickness in the copper-plated area than in the non-copper-plated area, a boundary pattern being formed at the demarcation between the copper-plated area and the non-copper-plated area. In the direction from the non-copper-plated area toward the copper-plated area, the distance between the border pattern from the middle outward and the edge of the corresponding side of the non-copper-plated area gradually decreases. When the platen roller reaches the boundary pattern position, the air can be squeezed from the middle to both sides along the boundary pattern, thus reducing the air bubbles at the junction of copper-plated and non-copper-plated areas.

### FIELD OF THE PRESENT DISCLOSURE

The present disclosure relates to circuit boards, especially relates to a circuit board.

### DESCRIPTION OF RELATED ART

Due to the thickness requirements of FPC (Flexible Printed Circuit) and PCB (Printed Circuit Board), part of the FPC line copper or invalid copper surface does not require copper plating. In the design, it will protect the non-plated copper area by dry film masking; then copper plating, forming a part of copper plating part of the non-plated copper structure, and finally by etching in the non-copper plated area and copper plated area to form the line.

In the related arts, the junction between the non-copper-plated area and the copper-plated area is generally designed with a straight border and has a high drop. When doing the line, the rolling machine presses laminating dry film from the non-copper-plated area towards the copper-plated area, the junction area of the height difference is easy to form air accumulation and air bubbles, in line etching, due to air bubbles, etching solution is easy to enter from the air bubble area and mistakenly etch the design line copper, resulting in line notches and poor products.

### SUMMARY OF THE INVENTION

The present disclosure provides a circuit board capable of reducing air bubbles at the junction of copper-plated and non-copper-plated areas when laminating a dry film, avoiding line gaps, and improving product application performance and lifespan.

The circuit board comprising a substrate layer and a conductive layer attached to one side of the substrate layer, the conductive layer being divided into a copper-plated area and a non-copper-plated area adjacent to the copper-plated area, the conductive layer having a greater thickness in the copper-plated area than in the non-copper-plated area, a boundary pattern being formed at the demarcation between the copper-plated area and the non-copper-plated area, wherein, the boundary pattern is curved from the middle outward in the direction from the non-copper-plated area to the copper-plated area.

Further, the boundary pattern is a curve.

Further, the boundary pattern is a circular arc.

Further, at least a portion of the boundary pattern is a straight line.

Further, the circuit board further includes a dry film layer attached to the side of the conductive layer that is away from the substrate layer.

Further, the dry film layer is pressed onto the conductive layer by rollers in the direction from the non-copper-plated area towards the copper-plated area.

Further, the dry film layer forms an etching pattern with hollowing.

Further, the etching pattern partially located in the copper-plated area; and/or, the etching pattern partially located in the non-copper-plated area.

Further, the boundary pattern is a symmetrical figure.

In the process of pressing the dry film to the circuit board of this solution, the direction of movement of the lamination roller is from the non-copper-plated area to the copper-plated area. As the boundary pattern is curved from the middle outward in the direction from the non-copper-plated area to the copper-plated area, the lamination roller touches the middle of the boundary pattern first when pressing into the copper-plated area, during the rolling of the lamination rollers, air can be squeezed from the middle to the sides along the border pattern, thus reducing the air bubbles at the junction of copper-plated area and non-copper-plated area, avoiding line notches during the etching process, improving the product application performance and lifespan, and making the final formed line width meet the requirements of IPC-6013 (Winding Printed Board Quality Requirements and Performance Specification), and the size of the line notches is less than 20% of the line width.

### BRIEF DESCRIPTION OF THE DRAWINGS

The present disclosure will hereinafter be described in detail with reference to an exemplary embodiment. To make the technical problems to be solved, technical solutions and beneficial effects of present disclosure more apparent, the present disclosure is described in further detail together with the figures and the embodiment. It should be understood the specific embodiment described hereby is only to explain this disclosure, not intended to limit this disclosure.

FIG. 1 is a structure schematic of a process of pressing laminating dry film of a circuit board in the related arts.

FIG. 2 is a structure schematic of a line after etching of the related arts.

FIG. 3 is a structure schematic of a process of pressing laminating dry film of a circuit board in the present disclosure.

FIG. 4 is a structure schematic of a line after etching of the present disclosure.

FIG. 5 is a cross-sectional view of the circuit board of the present disclosure.

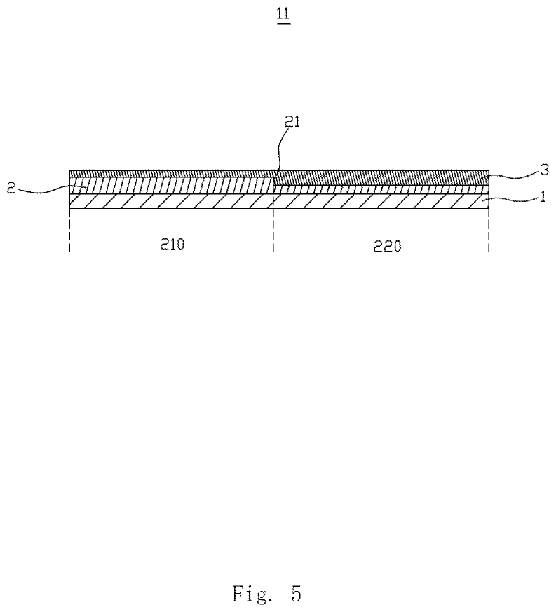

### DETAILED DESCRIPTION OF THE EXEMPLARY EMBODIMENT

The present disclosure will hereinafter be described in detail with reference to an exemplary embodiment. To make the technical problems to be solved, technical solutions and beneficial effects of the present disclosure more apparent, the present disclosure is described in further detail together with the figure and the embodiment. It should be understood the specific embodiment described hereby is only to explain the disclosure, not intended to limit the disclosure.

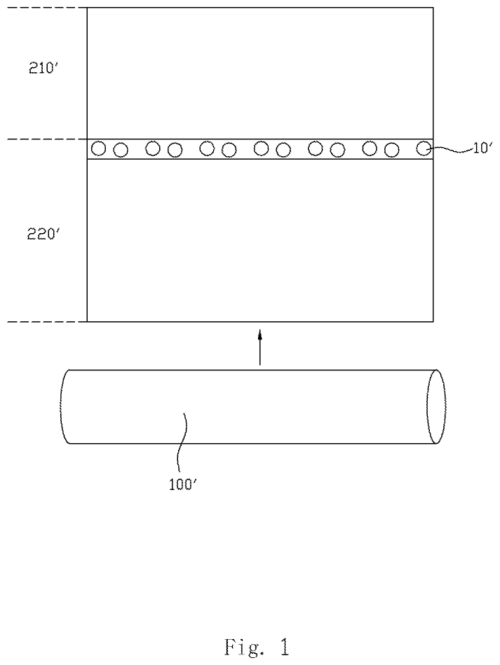

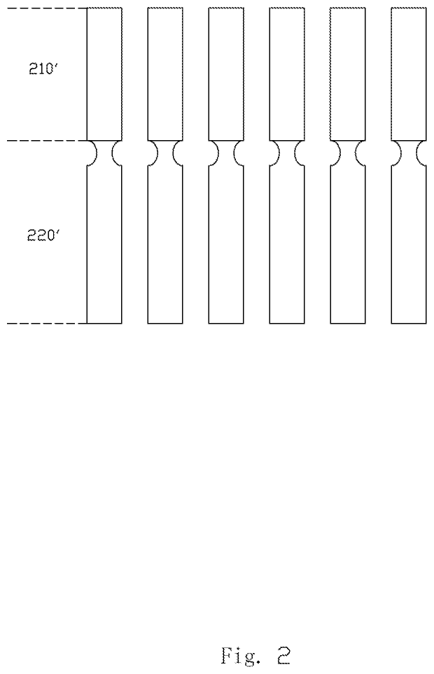

Please refer to FIG. 1, in the related arts, the boundary area between the conventional copper-plated area 210′ and the non-copper-plated area 220′ on the circuit board is generally designed with a linear boundary and has a height drop. In the process of pressing the dry film, the lamination roller 100′ moves from the non-copper-plated area 220′ towards the copper-plated area 210′ and in a direction perpendicular to the linear boundary. When the lamination roller 100′ reaches the linear boundary position, due to the height drop at the linear boundary, the film is unable to fit the position at the linear boundary completely, and the air tends to stay in the gap formed between the film and the linear boundary, thus bubbles 10′ appear. Combined with FIG. 2, in the process of forming the line by etching afterwards, if the line passes at the linear boundary, the bubble 10′ is easy to form a channel for the etchant to enter, making the etch notch of the designed line too large to meet the product requirements, resulting in a defective product.

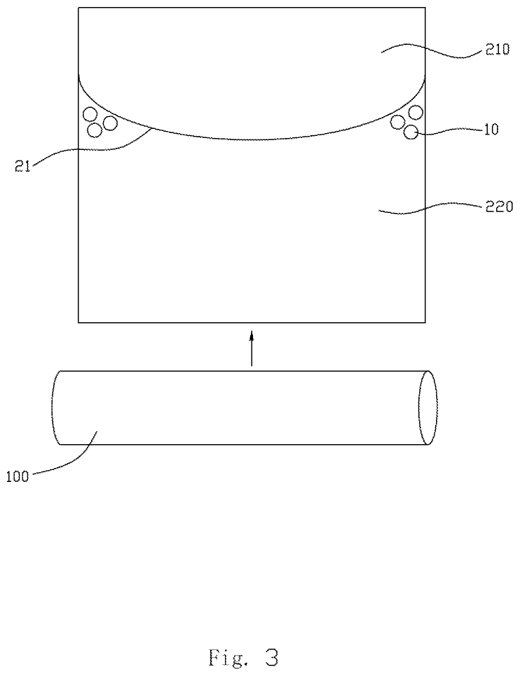

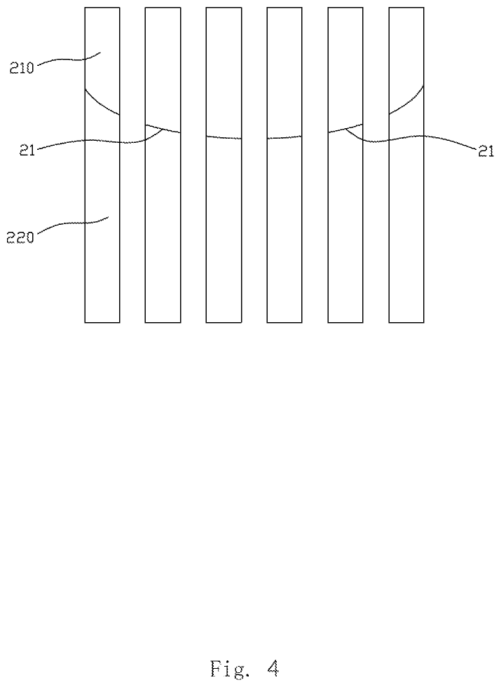

In the present disclosure, in combination with FIGS. 3-4, a circuit board 11 is provided, and the circuit board 11 may be an FPC board or a PCB board. The circuit board 11 comprising a substrate layer 1 and a conductive layer 2 attached to one side of the substrate layer 1, the conductive layer 2 being divided into a copper-plated area 210 and a non-copper-plated area 220 adjacent to the copper-plated area 210, the conductive layer 2 having a greater thickness in the copper-plated area 210 than in the non-copper-plated area 220, a boundary pattern 21 being formed at the demarcation between the copper-plated area 210 and the non-copper-plated area 220, the boundary pattern 21 is curved from the middle outward in the direction from the non-copper-plated area 220 to the copper-plated area 210.

In the process of pressing the dry film to the circuit board 11 of the present disclosure, the direction of movement of the lamination roller 100 is from the non-copper-plated area 220 to the copper-plated area 210. As the boundary pattern 21 is curved from the middle outward in the direction from the non-copper-plated area 220 to the copper-plated area 210, the lamination roller touches the middle of the boundary pattern 21 first when pressing into the copper-plated area 210, during the rolling of the lamination rollers 100, air can be squeezed from the middle to the sides along the border pattern 21, thus reducing the air bubbles 10 at the junction of copper-plated area and non-copper-plated area, avoiding line notches during the etching process, improving the product application performance and lifespan, and making the final formed line width meet the requirements of IPC-6013 (Winding Printed Board Quality Requirements and Performance Specification), and the size of the line notches is less than 20% of the line width.

Further, the boundary pattern 21 is a curve. Preferably, the boundary pattern 21 is a circular arc. Wherein, the boundary pattern 21 is raised from the copper-plated area 210 toward the non-copper-plated area 220. In this way, the outwardly protruding circular boundary is designed to follow the direction of operation of the laminating roller 100. During the lamination process of the lamination roller 100, from the non-copper-plated area 220 to the copper-plated area 210, the gas is driven forward by the lamination roller 100 along the edge of the curved design until it is discharged, and no air stays at the boundary pattern 21, so no air bubbles 10 are generated. In some embodiments, the boundary pattern 21 may also be elliptical arc-shaped. In some embodiments, the boundary pattern 21 may be at least partially straight, e.g., the boundary pattern 21 may be folded line shape, and when it is folded line shape, the fold line located on the outside is bent in a direction away from the non-copper-plated region 220 relative to the fold line located on the inside.

Further, the boundary pattern 21 is a symmetrical figure. The axis of symmetry of the boundary pattern 21 is parallel to the direction of operation of the laminating roller 100, so that the patterns on both sides of the axis of symmetry are the same and air is discharged in a more balanced manner.

The circuit board 11 further includes a dry film layer 3 attached to the side of the conductive layer 2 that is away from the substrate layer 1. The dry film layer 3 is used to cover the part of the conductive layer 2 that does not need to be etched in order to achieve protection of the corresponding part of the copper material. The dry film layer 3 is adhered to the conductive layer 2 by pressing the lamination roller 100 from the non-copper-plated area 220 toward the copper-plated area 210, using this processing method to minimize the air retention in the boundary pattern 21.

The dry film layer 3 forms an etching pattern with hollowing. The etching pattern partially located in the copper-plated area 210; and/or, the etching pattern partially located in the non-copper-plated area 220. In this embodiment, part of the etching pattern is located in the copper-plated area 210, and the other part is located in the non-copper-plated area 220, so that after etching the conductive layer 2, the copper material at the corresponding position of the etching pattern will be eliminated, the leaving material forms the circuit. Due to the setting of the boundary pattern 21 as previously described, the circuit is less prone to side etching of the wire at the location of the boundary pattern 21, with smaller notches and higher product yields.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A circuit board comprising: a substrate layer and a conductive layer attached to one side of the substrate layer, the conductive layer being divided into a copper-plated area and a non-copper-plated area adjacent to the copper-plated area, the conductive layer having a greater thickness in the copper-plated area than in the non-copper-plated area, a boundary pattern being formed at the demarcation between the copper-plated area and the non-copper-plated area, wherein, the boundary pattern is curved from the middle outward in the direction from the non-copper-plated area to the copper-plated area.

2. The circuit board as described in claim 1, wherein the boundary pattern is a curve.

3. The circuit board as described in claim 2, wherein the boundary pattern is a circular arc.

4. The circuit board as described in claim 1, wherein at least a portion of the boundary pattern is a straight line.

5. The circuit board as described in claim 1, wherein the circuit board further includes a dry film layer attached to the side of the conductive layer that is away from the substrate layer.

6. The circuit board as described in claim 5, wherein the dry film layer is pressed onto the conductive layer by rollers in the direction from the non-copper-plated area towards the copper-plated area.

7. The circuit board as described in claim 5, wherein the dry film layer forms an etching pattern with hollowing.

8. The circuit board as described in claim 7, wherein the etching pattern partially located in the copper-plated area; and/or, the etching pattern partially located in the non-copper-plated area.

9. The circuit board as described in claim 1, wherein the boundary pattern is a symmetrical figure.
